(19) United States
(12) Patent Application Publication
(10) Pub. No.: US 2026/0271768 A1
(43) Pub. Date: Sep. 10, 2026

(54) POWER SEMICONDUCTOR PACKAGE INCLUDING STACKED CONTACT CLIPS, SYSTEM AND METHOD FOR FABRICATING A POWER SEMICONDUCTOR PACKAGE

(71) Applicant: Infineon Technologies AG, Neubiberg (DE)

(72) Inventors: Thorsten Scharf, Lappersdorf (DE); Michael Bauer, Nittendorf (DE); Johann Gatterbauer, Parsberg (DE); Andreas Grassmann, Sinzing (DE); Uwe Schindler, Reichenbach (DE); Stefan Schwab, Regensburg (DE); Franz Zollner, Sinzing (DE)

(21) Appl. No.: 19/546,696

(22) Filed: Feb. 23, 2026

(30) Foreign Application Priority Data
Mar. 4, 2025 (DE) 102025108105.0

(51) Int. Cl. H10W 72/60; H10W 72/00; H10W 90/00; H10W 90/10

(52) U.S. Cl. CPC H10W 72/637; H10W 72/076; H10W 72/627; H10W 72/634; H10W 90/10; H10W 90/763; H10W 90/764

(57) ABSTRACT

A power semiconductor package includes: power semiconductor dies arranged on and electrically coupled to an electrically conductive layer such that a first side of the dies faces the electrically conductive layer, the dies forming a half bridge circuit including at least one low side die and at least one high side die; a first contact clip connecting a first type power electrode of the low side die to a second type power electrode of the high side die, the second type power electrode being arranged on a second side of the high side die, and the first contact clip being arranged above the second side of the high side die; a second contact clip electrically connected to a first type power electrode on the first side of the high side die and having an upper portion arranged vertically above the first contact clip; and a molded body encapsulating the dies.

### TECHNICAL FIELD

The present disclosure relates to a power semiconductor package, in particular a power semiconductor package comprising stacked contact clips, as well as to a system and to a method for fabricating a power semiconductor package.

### BACKGROUND

A power semiconductor package may for example comprise an electrical circuit like a half bridge circuit, a full bridge circuit, a converter circuit, an inverter circuit, etc. Such a circuit comprises a plurality of power semiconductor dies which are arranged on a power electronic substrate and which are electrically connected together via the substrate as well as via connectors like for example contact clips. Power electronic substrates, for example substrates of the type direct bonded copper (DBC), may be comparatively expensive and may therefore contribute a significant share to the overall costs of the power semiconductor package. It may therefore be desirable to reduce the required size of the substrate in a power semiconductor package. Furthermore, the coefficient of thermal expansion of metal components like contact clips may be considerable different from the coefficient of thermal expansion of a molded body of a power semiconductor package. This difference may for example cause warpage and/or delamination issues. Improved power semiconductor packages, improved systems comprising a power semiconductor package and improved methods for fabricating a power semiconductor package may help with solving these and other problems.

### SUMMARY

Various aspects pertain to a power semiconductor package, comprising: a power electronic substrate comprising at least a first electrically conductive layer arranged on an electrically insulating layer, a plurality of power semiconductor dies arranged on and electrically coupled to the first electrically conductive layer such that a first side of the power semiconductor dies faces the first electrically conductive layer, wherein the power semiconductor dies form a half bridge circuit comprising at least one low side die and at least one high side die, a first contact clip connecting a first type power electrode of the low side die to a second type power electrode of the high side die, wherein the second type power electrode of the high side die is arranged on a second side of the high side die, opposite the first side, and wherein the first contact clip is arranged above the second side of the high side die, a second contact clip electrically connected to a first type power electrode on the first side of the high side die, wherein an upper portion of the second contact clip is arranged vertically above the first contact clip, and a molded body encapsulating the power semiconductor dies.

Various aspects pertain to a system, comprising: the power semiconductor package as outlined above, and a first type DC busbar and a second type DC busbar configured to electrically connect the power semiconductor package to a DC link capacitor, wherein the first type DC busbar and the second type DC busbar are at least partially arranged in two parallel planes.

Various aspects pertain to a method for fabricating a power semiconductor package, the method comprising: providing a power electronic substrate comprising at least a first electrically conductive layer arranged on an electrically insulating layer, arranging a plurality of power semiconductor dies on the first electrically conductive layer such that a first side of the power semiconductor dies faces the first electrically conductive layer and electrically coupling the power semiconductor dies to the first electrically conductive layer, wherein the power semiconductor dies form a half bridge circuit comprising at least one low side die and at least one high side die, connecting a first type electrode of the low side die to a second type electrode of the high side die using a first contact clip, wherein the second type electrode of the high side die is arranged on a second side of the high side die, opposite the first side, and wherein the first contact clip is arranged above the second side of the high side die, connecting a second contact clip to a first type electrode on the first side of the high side die, wherein an upper portion of the second contact clip is arranged vertically above the first contact clip, and encapsulating the power semiconductor dies with a molded body.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIGS. 1A and 1B illustrate a power semiconductor package comprising a first and a second contact clip arranged in a stack above each other. FIG. 1A illustrates the power semiconductor package without a molded body and FIG. 1B shows the power semiconductor package after molding.

FIGS. 2A and 2B illustrate a further power semiconductor package comprising a first and a second contact clip arranged in a stack above each other, wherein the second contact clip is exposed from a first side of the molded body and provides a power terminal of the power semiconductor package. FIG. 2A illustrates the power semiconductor package without a molded body and FIG. 2B shows the power semiconductor package after molding.

FIG. 3 illustrates a system comprising the power semiconductor package of FIGS. 2A and 2B as well as first and second type DC busbars configured to connect the power semiconductor package to e.g. a DC link capacitor.

FIGS. 4A to 4C illustrate a further power semiconductor package comprising stacked contact clips, wherein power terminals are connected to the substrate via connectors like clips or ribbons. Note that FIGS. 4A to 4C show the power semiconductor package prior to molding.

FIG. 5 illustrates an exemplary leadframe which may be used during fabrication of a power semiconductor package in order to provide a second contact clip and external terminals of the power semiconductor package.

FIG. 6 illustrates a further power semiconductor package comprising stacked contact clips and further comprising an additional metal bar configured to reduce warpage of the power semiconductor package and/or to provide an attachment point for an electrical connection to the substrate.

FIG. 7 is a flow chart of an exemplary method for fabricating a power semiconductor package.

FIG. 8 illustrates a power semiconductor package comprising a metal plate provided at the top side of the encapsulation.

### DETAILED DESCRIPTION

In the following detailed description, known structures and elements are shown in schematic form in order to facilitate describing one or more aspects of the disclosure. In this regard, directional terminology, such as "top", "bottom", "left", "right", "upper", "lower" etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms "include", "have", "with" or other variants thereof are used in either the detailed description or the claims, such terms are intended to be inclusive in a manner similar to the term "comprise". The terms "coupled" and "connected", along with derivatives thereof may be used. It should be understood that these terms may be used to indicate that two elements cooperate or interact with each other regardless whether they are in direct physical or electrical contact, or they are not in direct contact with each other; intervening elements or layers may be provided between the "bonded", "attached", or "connected" elements. However, it is also possible that the "bonded", "attached", or "connected" elements are in direct contact with each other. Also, the term "exemplary" is merely meant as an example, rather than the best or optimal.

The examples of a power semiconductor package described below may use various types of semiconductor dies or circuits incorporated in the semiconductor dies, among them AC/DC or DC/DC converter circuits, power MOS transistors, power Schottky diodes, JFETs (Junction Gate Field Effect Transistors), power bipolar transistors, power integrated circuits, etc. The examples may also use semiconductor chips comprising MOS transistor structures or vertical transistor structures like, for example, IGBT (Insulated Gate Bipolar Transistor) structures or, in general, transistor structures in which at least one electrode is arranged on a first main side of the semiconductor die and at least one other electrode is arranged on a second main side of the semiconductor die, opposite to the first main side.

The semiconductor die(s) can be manufactured from a specific semiconductor material, for example Si, SiC, SiGe, GaAs, GaN, or from any other semiconductor material, and, furthermore, may contain one or more of inorganic and organic materials that are not semiconductors, such as for example insulators, plastics or metals.

An efficient power semiconductor package, an efficient system comprising a power semiconductor package and an efficient method for fabricating a power semiconductor package may for example reduce material consumption, ohmic losses, chemical waste, etc. and may thus enable energy and/or resource savings. Improved power semiconductor packages, improved systems comprising a power semiconductor package and improved methods for fabricating a power semiconductor package, as specified in this description, may thus at least indirectly contribute to green technology solutions, i.e. climate-friendly solutions providing a mitigation of energy and/or resource use.

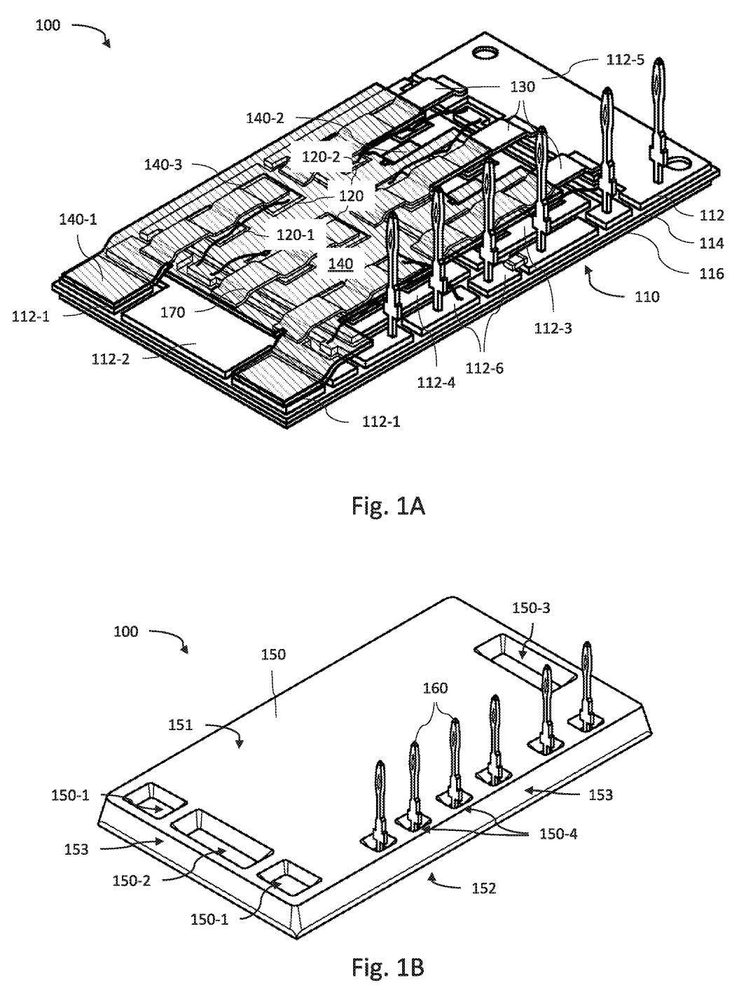

FIGS. 1A and 1B schematically show a perspective view of a power semiconductor package 100 comprising a power electronic substrate 110, a plurality of power semiconductor dies 120, a first contact clip 130, a second contact clip 140 and a molded body 150. Note that FIG. 1A shows the power semiconductor package 100 without the molded body 150 and FIG. 1B shows the power semiconductor package 100 with the molded body 150. Further note that in FIG. 1A the second contact clip 140 is drawn as transparent in order to show the power semiconductor dies 120 and the first contact clip 130 below the second contact clip 140.

The power semiconductor package 100 may be configured to operate with a high voltage, e.g. a voltage of about 400V or more, or about 800V or more, or about 1.2kV or more and/or a strong current, for example a current of about 1A or more, or about 100A or more, or about 500A or more. The power semiconductor package 100 may comprise any suitable electrical circuit, for example a half bridge circuit, a full bridge circuit, a converter circuit, an inverter circuit, etc.

The power semiconductor package 100 may be configured for use in any suitable application, for example automotive applications, industrial applications or household applications. According to a specific example, the power semiconductor package 100 may be part of an electric engine, for example part of the main inverter of an electric engine of an electric vehicle.

The power electronic substrate 110 comprises at least a first electrically conductive layer 112 arranged on an electrically insulating layer 114. The power electronic substrate 110 may additionally comprise a second electrically conductive layer 116 arranged on an opposite side of the electrically insulating layer 114 as the first electrically conductive layer 112.

The power electronic substrate 110 may for example be a substrate of the type direct bonded copper (DBC), direct bonded aluminum (DBA), active metal braze (AMB) or insulated metal substrate (IMS). A lower side of the power electronic substrate 110, in particular the second electrically conductive layer 116, may be at least partially exposed from the molded body 150 and may be configured to be coupled to a heatsink or alternatively configured to be in direct contact with a cooling fluid. According to an example, part of the first electrically conductive layer 112 is exposed from the molded body 150 in order to provide external contacts of the power semiconductor package 100, as described in more detail further below.

The power semiconductor dies 120 are arranged on and electrically coupled to the first electrically conductive layer 112, such that a first side of the power semiconductor dies 120 faces the first electrically conductive layer 112 and an opposite second side faces away from the power electronic substrate 110. The power semiconductor dies 120 may for example be coupled to the first electrically conductive layer 112 via solder joints, sintered joints or joints comprising an electrically conductive glue.

The power semiconductor dies 120 form a half bridge circuit comprising at least one low side die 120-1 and at least one high side die 120-2 of the half bridge. The power semiconductor package 100 may comprise any suitable number of power semiconductor dies 120, for example two, four, six, eight, etc. In the example shown in FIG. 1A, the power semiconductor package 100 comprises six low side dies 120-1 and six high side dies 120-2, respectively connected in parallel.

According to an example, the power semiconductor dies 120 are all of the same type of die and according to another example, different types of dies are comprised in the power semiconductor package 100.

According to an example, the power semiconductor dies 120 are arranged “drain-down” on the power electronic substrate 110, meaning that the drain electrode faces the substrate 110 and is electrically connected to the substrate 110. However, it is also possible that the power semiconductor dies 120 are arranged “source-down” instead. In the latter case, the direction of the half bridge circuit may be the reverse of what is shown in FIG. 1A, meaning that the dies 120-1 may be the high side dies and the dies 120-2 may be the low side dies of the half bridge.

As shown in FIG. 1A, the first electrically conductive layer 112 may for example comprise at least first to fifth pads 112-1 to 112-5, wherein the high side die 120-2 may be arranged on the third pad 112-3 and the low side die 120-1 may be arranged on the fourth pad 112-4.

According to the example shown in FIG. 1A, the third and fourth pads 112-3, 112-4 are arranged laterally next to each other. Furthermore, first edges of the third and fourth pads 112-3, 112-4 may be part of an outer edge region (the upper left edge region in FIG. 1A) of the power electronic substrate 110, the first edges being parallel to each other. The first electrically conductive layer 112 and thus the first edges of the third and fourth pads 112-3, 112-4 may be slightly pulled back with respect to the electrically insulating layer 114, such that the edge of the electrically insulating layer 114 and the first edges do not form a common edge.

The first contact clip 130 connects a first type power electrode of the low side die 120-1 to a second type power electrode of the high side die 120-2. As outlined above, the first type power electrode may be the source electrode or the emitter electrode of the low side die 120-1 and the second type power electrode may be the drain electrode or the collector electrode of the high side die 120-2. According to another example, it is the other way around.

The first contact clip 130 may be a metal clip and may comprise or consist of any suitable metal or metal alloy. For example, the first contact clip 130 may comprise or consist of Al or Cu. The first contact clip 130 may be part of a clip frame and may be singulated from the clip frame during fabrication of the power semiconductor package 100.

As shown in FIG. 1A, a first end of the first contact clip 130 may be coupled to the fourth pad 112-4 and an opposite second end may be coupled to the fifth pad 112-5 of the first electrically conductive layer 112 of the substrate 110. The first contact clip 130 may be coupled to the first electrically conductive layer 112 via any suitable joint, for example a solder joint, a sintered joint, a welded joint, etc.

According to an example, the power semiconductor package 100 comprises a single first contact clip 130. According to another example, the power semiconductor package 100 comprises a plurality of first contact clips 130 connected in parallel (see the example shown in FIG. 1A).

The second type power electrode of the high side die 120-2 is arranged on a second side of the high side die 120-2, opposite the first side. Note that the second side of the high side die 120-2 faces away from the substrate 110. The first contact clip 130 is arranged above the second side of the high side die 120-2 and may be coupled to the second type power electrode via e.g. a solder joint, a sintered joint or a joint comprising conductive glue.

The second contact clip 140 is electrically connected to a first type power electrode on the first side of the high side die 120-2, for example via the first electrically conductive layer 112. In the example shown in FIG. 1A, the first side of the high side die 120-2 and the second contact clip 140 (in particular a second lower portion 140-2, see further below) are both coupled to the third pad 112-3 of the electrically conductive layer 112.

An upper portion 140-3 of the second contact clip 140 is arranged vertically above the first contact clip 130. In the example shown in FIG. 1A, the upper portion 140-3 is also arranged vertically above all of the power semiconductor dies 120. According to another example, the upper portion 140-3 may instead be arranged vertically above only some of the power semiconductor dies 120. However, it may be desirable that the upper portion 140-3 overlays as many of the power semiconductor dies 120 and/or as much of the first contact clip 130 as technically feasible in order to reduce stray inductances in the power semiconductor package 100 and/or to reduce package warpage.

As shown in FIG. 1B, the molded body 150 encapsulates the power semiconductor dies 120. The molded body 150 may be fabricated using any suitable molding technique, for example compression molding, injection molding or transfer molding.

According to an example, the first and second contact clips 130, 140 are completely encapsulated by the molded body 150. According to another example, the first contact clip 130 and/or the second contact clip 140 is at least partially exposed from the molded body 150. The exposed part(s) of the first and/or second contact clip 130, 140 may be configured to act as external terminal(s) of the power semiconductor package 100.

In the example shown in FIG. 1B, the molded body 150 comprises first to third openings 150-1 to 150-3 arranged in a first side 151 of the molded body 150. The first side 151 of the molded body 150 faces away from the power electronic substrate 110. The power electronic substrate 110 may be exposed from the molded body 150 at a second side 152, opposite the first side 151. Lateral sides 153 of the molded body 150 connect the first and second sides 151, 152.

The first pads 112-1 of the first electrically conductive layer 112 may be exposed from the first openings 150-1. However, it is also possible that the first pads 112-1 are not exposed from the first openings 150-1 because the first lower portions 140-1 of the second contact clip 140 are exposed from the first openings 150-1 (see also FIG. 1A). According to another example, the lower portions 140-1 only partially cover the first pads 112-1 such that both the lower portions 140-1 and the first pads 112-1 are exposed from the first openings 150-1. The exposed first pads 112-1 and/or the exposed lower portions 140-1 may form first type DC power terminals of the power semiconductor package 100. According to a first example, the first type DC power terminals are DC+ terminals and according to a second example, the first type DC power terminals are DC- terminals.

The second pad 112-2 of the first conductive layer 112 may be exposed from the molded body 150 at the second opening 150-2. The exposed second pad 112-2 may form a second type DC power terminal of the power semiconductor package 100, i.e. a DC- terminal according to the first example or a DC+ terminal according to the second example.

The fifth pad 112-5 of the first conductive layer 112 may be exposed from the molded body 150 at the third opening 150-3. The exposed fifth pad 112-5 may form a phase current terminal of the power semiconductor package 100. Alternatively or in addition, the clip 130 may extend above parts of the fifth pad 112-5 of the first conductive layer 112 and instead of exposing the fifth pad 112-5 of the first conductive layer 112, the clip surface itself is exposed.

The power semiconductor package 100 may also comprise at least one third contact clip 170 connecting the second pad 112-2 of the first electrically conductive layer 112 to a second type electrode of the low side die 120-1. According to an example, a lower portion of the third contact clip 170 is exposed from the molded body 150 at the second opening 150-2 and forms the second type DC power terminal of the power semiconductor package 100. According to another example, the lower portion of the third contact clip 170 is not exposed and the second pad 112-2 alone forms the second type DC power terminal (see FIG. 1A). According to yet another example, both the second pad 112-2 and the lower portion are partially exposed at the second opening 150-2.

The third contact clip 170 may be arranged partially or completely below the second contact clip 140 (see FIG. 1A). In other words, the upper portion of the second contact clip 140 may be arranged vertically above the third contact clip 170.

As shown in FIG. 1B, the molded body 150 may comprise one or more further openings 150-4, which may also be arranged in the first side 151. The further opening(s) 150-4 may be configured to provide access to one or more further pads 112-6 of the first conductive layer 112. According to an example, pins 160, in particular press fit pins, or solderable pins, or flex cards, or adapters, may be arranged in the further openings 150-4. The pins 160 may be configured to act as gate terminals and/or sensing terminals of the power semiconductor package 100 and may for example be configured to be connected to a driver board above the first side 151 of the molded body 150.

In the example shown in FIG. 1B, the molded body 150 comprises the openings 150-1 to 150-4 in order to provide external terminals of the power semiconductor package 100. However, it is also possible that instead of the depicted openings extending into the molded body 150, the respective external terminals may be level with the first side 151 of the molded body 150. Furthermore, in the example shown in FIG. 1B, the power semiconductor package 100 does not comprise any external terminals at the lateral sides 153 of the molded body 150. In this case, the power semiconductor package 100 may be configured to be connected from above the first side 151 for both power connection purposes, e.g. to a DC link capacitor, and for control connection purposes, e.g. to a driver board. According to another example, external terminals may also be arranged at one or more of the lateral sides 153 of the molded body 150. The second side 152 of the molded body 150 may be configured to face a heatsink.

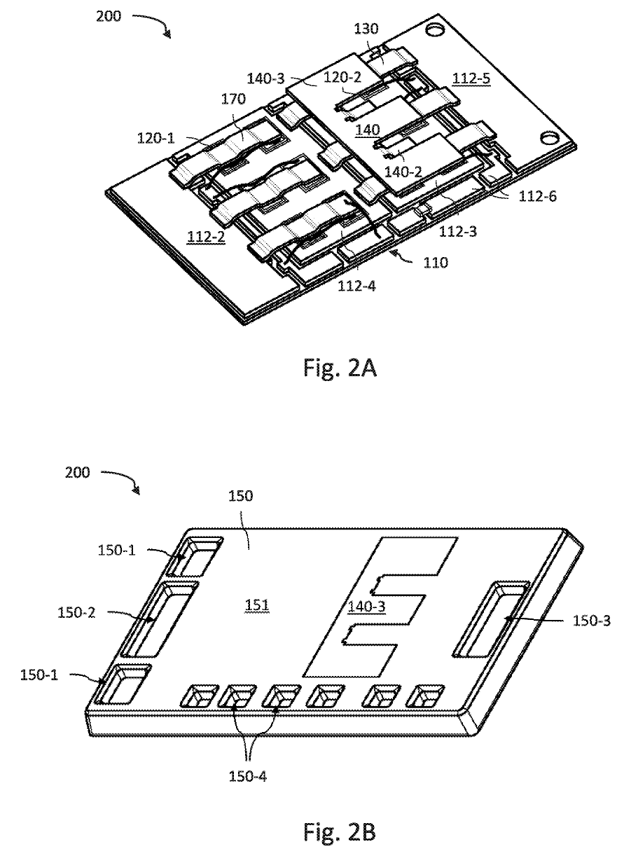

FIGS. 2A and 2B show a further power semiconductor package 200 which may be similar or identical to the power semiconductor package 100, except for the differences described in the following. Note that FIG. 2A shows the power semiconductor package 200 without the molded body 150 and FIG. 2B shows the power semiconductor package 200 after molding.

In particular, in the power semiconductor package 200, the upper portion 140-3 of the second contact clip 140 is at least partially exposed from the molded body 150, in particular from the first side 151 of the molded body 150 (see FIG. 2B). The exposed upper portion 140-3 forms a first type DC power terminal of the power semiconductor package 200.

As shown in FIG. 2A, the power semiconductor package 200 does not necessarily comprise the first pads 112-1 on the first electrically conductive layer 112. The first pads 112-1 are not necessary because the exposed upper portion 140-3 of the second contact clip 140 already provides the first type DC power terminal. In other words, in the semiconductor package 200, only one of the DC power terminals is provided by the substrate and the other DC power terminal is provided by the second contact clip 140. The power semiconductor package 200 may therefore have a smaller footprint on the substrate 110 than the power semiconductor package 100, according to an example. Furthermore, this means that the first type DC power terminal (provided by the exposed upper portion 140-3) is arranged in a first plane and the second type DC power terminal (provided by the second pad 112-2 of the substrate 110) is arranged in a second plane which is below the first plane. The first and second planes may in particular be parallel to each other.

Furthermore, the second contact clip 140 does not necessarily extend to a point vertically above the low side die(s) 120-1 (and the third contact clip(s) 170) and may be arranged solely above the high side die(s) 120-2 and the first contact clip(s) 130 (see FIG. 2A). However, it is also possible that the second contact clip 140 does extend to a point above the low side die(s) 120-1 and above the third contact clip(s) 170, for example in order to improve the electrical, mechanical and/or thermal properties of the power semiconductor package 200.

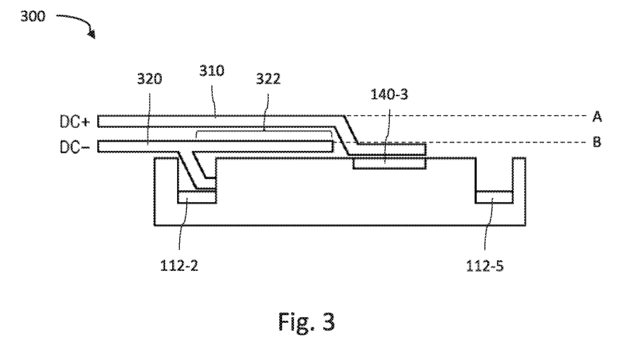

FIG. 3 shows a side view of a system 300 comprising the power semiconductor package 200, a first type DC busbar 310 connected to the first type DC power terminal of the power semiconductor package 200 (i.e. the exposed upper portion 140-3 of the second contact clip 140) and a second type DC busbar 320 connected to the second type DC power terminal (i.e. the second pad 112-2). A further exemplary system comprises the power semiconductor package 100 instead of the power semiconductor package 200 connected to the first and second type DC busbars 310, 320 in an analogous manner.

The first and second type DC busbars 310, 320 may be configured to electrically connect the power semiconductor package 200 to a DC link capacitor. The first and second type DC busbars 310, 320 may be at least partially arranged in two parallel planes (planes A and B in FIG. 3). This may help with reducing stray inductances in the system 300.

According to an example, the second type DC busbar 320 comprises a dummy portion 322, wherein a direct current path between the DC link capacitor and the power semiconductor package 200 does not go through the dummy portion 322. The dummy portion 322 is configured to extend a length of a portion of the second type DC busbar 320 that is parallel to the first type DC busbar 310, thereby reducing stray inductances in the system 300.

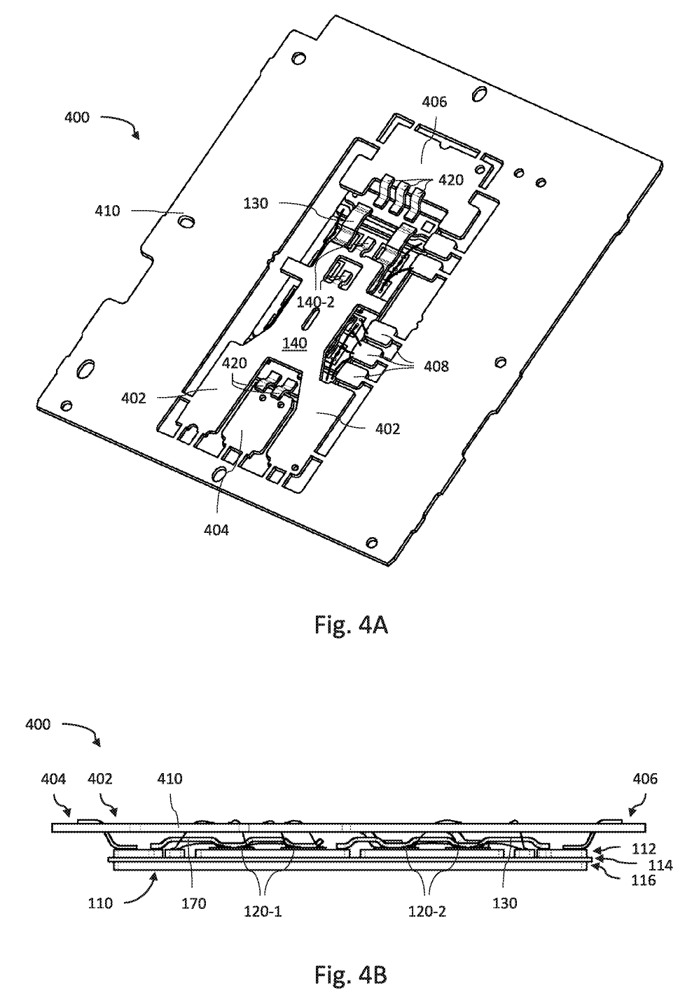

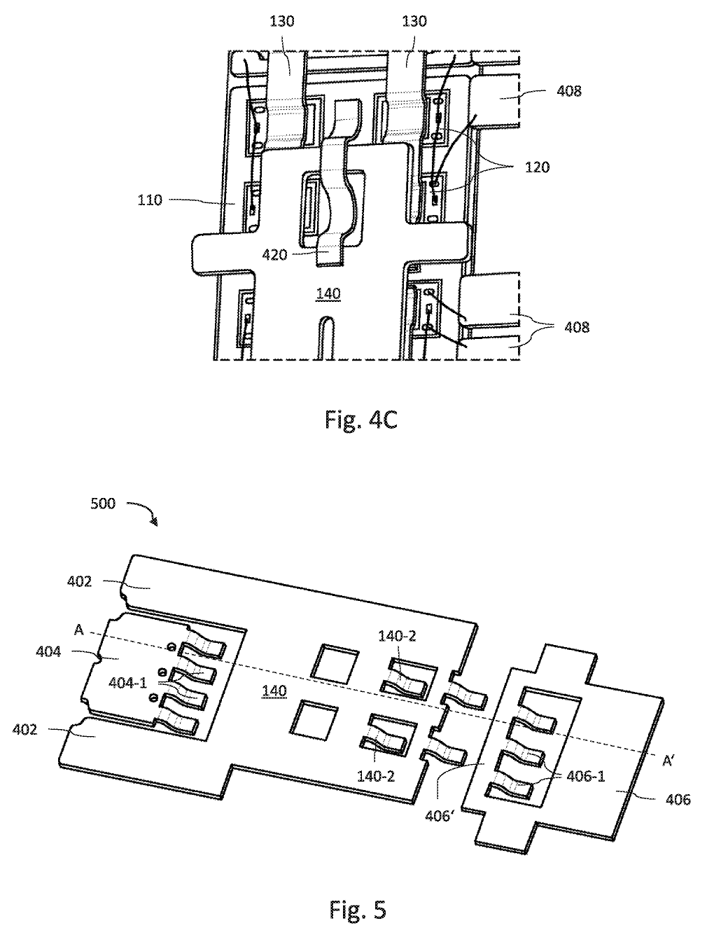

FIGS. 4A and 4B show a further power semiconductor package 400 during fabrication, wherein the molded body 150 has not yet been formed. FIG. 4A shows a perspective view and FIG. 4B shows a sectional view of the power semiconductor package 400. The power semiconductor package 400 may be similar or identical to the power semiconductor package 100 or 200, except for the differences described in the following.

In particular, the power semiconductor package 400 does not necessarily comprise any pads of the first electrically conductive layer 112 which are exposed from the molded body 150. Instead, the first and second type DC power terminals 402, 404 and the phase current terminal 406 may be provided by e.g. a leadframe. The first type DC power terminal(s) 402 may be provided by the second contact clip 140. The second contact clip 140, the second type DC power terminal 404 and the phase current terminal 406 may be provided as parts of a common leadframe 410, wherein fabricating the power semiconductor package 400 comprises singulated the second contact clip 140 and the terminals 404, 406 from the leadframe 410.

According to an example, the first and third contact clips 130, 170 are not part of the leadframe 410. Instead, the first and third contact clips 130, 170 may for example be provided as parts of one or more further leadframe or the first and third contact clips 130, 170 may be provided via a pick-and-place process.

As shown in FIG. 4B, the terminals 402, 404 and 406 may all be arranged above the substrate 110 and also above the first and third contact clips 130, 170. The terminals 402, 404 and 406 may in particular be arranged in a common plane. According to an example, the power semiconductor package 400 may comprise further terminals 408, e.g. sensing terminals and/or control terminals, which may also be provided as parts of the leadframe 410.

In the example shown in FIGS. 4A and 4B, the power semiconductor package 400 does not comprise any external terminals on the first electrically conductive layer 112 of the substrate 110. In other words, the molded body 150 of the power semiconductor package 400 does not necessarily comprise any of the openings 150-1 to 150-4 extending down to the substrate 110.

According to an example, the power semiconductor package 400 further comprises connectors 420 connecting parts of the leadframe 410 to the substrate 110. The connectors 420 may for example comprise or consist of ribbons, wires, and/or metal clips. In the example shown in FIGS. 4A and 4B, the second type DC power terminal 404 and the phase current terminal 406 are connected to the substrate 110 via the connectors 420 and the second contact clip 140 (i.e. the first type DC power terminal 402) is connected to the substrate 110 via the second lower portion(s) 140-2 of the second contact clip 140. In other words, the first type DC power terminal 402 and the connecting portion towards the substrate 110 are a monolithic part and the second type DC power terminal 404 and the phase current terminal 406 and their respective connecting portions towards the substrate 110 are no monolithic parts.

FIG. 4C shows a detail view of a different example of the power semiconductor package 400. In the example shown in FIG. 4C, the second contact clip 140 does not comprise a lower portion for connecting the first type DC power terminal 402 to the substrate 110. Instead, the first type DC power terminal 402 is connected to the substrate 110 via a connector 420, similar to the second type DC power terminal 404 and the phase current terminal 406.

FIG. 5 shows a leadframe 500 which may be similar or identical to the leadframe 410, except for the differences described in the following. The leadframe 500 may be used in place of the leadframe 410 during fabrication of a power semiconductor package like the power semiconductor package 400.

The leadframe 500 may comprise lower portions 140-1 of the second contact clip 140, lower portions 404-1 of the second type DC power terminal 404 and lower portions 406-1 of the phase current terminal 406. The lower portions 140-2, 404-1 and 406-1 are configured to electrically connect the second contact clip 140, the second type DC power terminal 404 and the phase current terminal 406 to the substrate. The lower portions 140-2, 404-1 and 406-1 are monolithic parts with the second contact clip 140, the second type DC power terminal 404 and the phase current terminal 406, respectively.

As shown in FIG. 5, the lower portions 140-2, 404-1 and 406-1 may all have the same orientation (FIGS. 4A and 4B show an example, wherein some of the connectors 420 have a different orientation than the lower portions 140-1). The lower portions 140-2, 404-1 and 406-1 all having the same orientation may reduce stress introduced in the power semiconductor package 400 by the spring force exercised by the lower portions 140-2, 404-1 and 406-1 compared to the case that lower portions with different orientations are used.

In the example shown in FIG. 5, the phase current terminal 406 comprises an additional beam 406’ compared to the leadframe 410 shown in FIG. 4A in order for the lower portions 406-1 to have the same orientation as the lower portions 140-2 and 404-1. According to another example, the second type DC power terminal 404 comprises such an additional beam instead and the orientation of the lower portions 140-2, 404-1 and 406-1 is rotated 180°.

According to another example, the leadframe 500 does not comprise the lower portions 140-2, 404-1 and 406-1 but instead comprises the connectors 420 (see FIG. 4C). In this case, the connectors 420 may all have the same orientation, similar to what is shown in FIG. 5 with respect to the lower portions 140-2, 404-1 and 406-1.

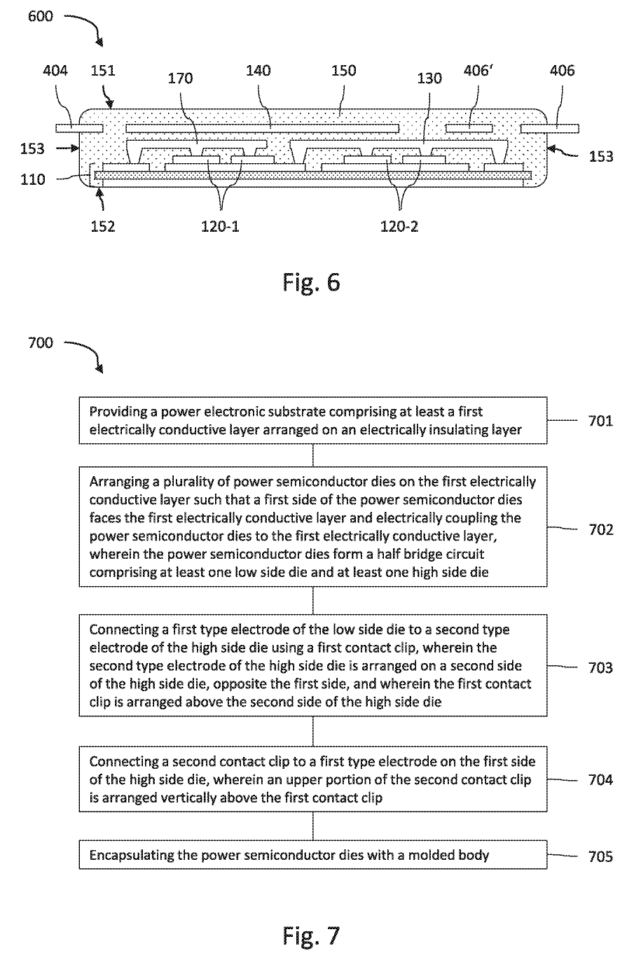

FIG. 6 shows a sectional view of a further power semiconductor package 600 which may be similar or identical to the power semiconductor packages 100 to 400, except for the differences described in the following. Note that the sectional view of FIG. 6 corresponds to a cut of the leadframe 500 along the line A-A’ in FIG. 5.

As shown in FIG. 6, the power semiconductor package 600 has a comparatively high metal content on the left hand side of FIG. 6, i.e. above the low side dies 120-1, due to the presence of the second contact clip 140. Without the additional bar 406’, the metal content on the right hand side of FIG. 6, i.e. above the high side dies 120-2, would be considerable lower than on the left hand side, which could increase warpage of the power semiconductor package 600. The additional bar 406’ therefore may provide the benefit of reduced package warpage and it may consequently be desirable to make use of the additional bar 406’ even in the case that the additional bar 406’ is not required as an attachment point for the lower portions 406-1.

According to the example shown in FIG. 6, the terminals 402, 404 and 406 are all exposed from the molded body 150 at one or more of the lateral sides 153 and none of the terminals 402-406 is exposed from the first side 151 of the molded body 150. According to another example, one or more or even all of the terminals 402-406 may be exposed from the first side 151, similar to the power semiconductor packages 100 and 200.

FIG. 7 is a flow chart of an exemplary method 700 for fabricating a power semiconductor package. The method 700 may for example be used for fabricating any of the power semiconductor packages 100 to 600.

The method 700 comprises at 701 a process of providing a power electronic substrate comprising at least a first electrically conductive layer arranged on an electrically insulating layer; at 702 a process of arranging a plurality of power semiconductor dies on the first electrically conductive layer such that a first side of the power semiconductor dies faces the first electrically conductive layer and electrically coupling the power semiconductor dies to the first electrically conductive layer, wherein the power semiconductor dies form a half bridge circuit comprising at least one low side die and at least one high side die; at 703 a process of connecting a first type electrode of the low side die to a second type electrode of the high side die using a first contact clip, wherein the second type electrode of the high side die is arranged on a second side of the high side die, opposite the first side, and wherein the first contact clip is arranged above the second side of the high side die; at 704 a process of connecting a second contact clip to a first type electrode on the first side of the high side die, wherein an upper portion of the second contact clip is arranged vertically above the first contact clip; and at 705 a process of encapsulating the power semiconductor dies with a molded body.

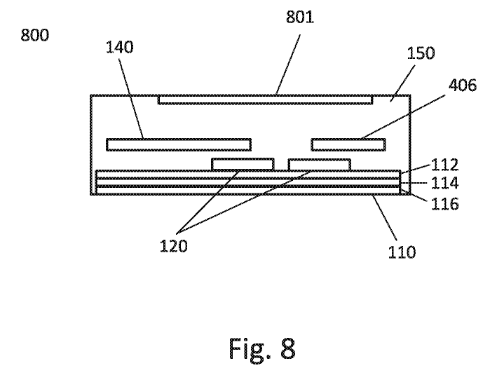

FIG. 8 shows a further example of a power module 800 in which a metal plate 801 is provided at the top side of the encapsulation, e.g. a molded body. The power module 800 may be any of the power module described herein above, e.g. in FIGS. 1-6. Identical reference numerals in FIG. 8 refer to respective features as described in detail in FIGS. 1-6. As shown in FIG. 8 the metal plate 801 is exposed from the encapsulation. The metal plate 801 is not connected to the internal circuitry of the power module 800. The metal plate 801 may reduce the overall stray inductance of the power module. The metal plate 801 may comprise or consist of copper. To guarantee a defined distance to the power lines of the power module 800 and to enable easy adaptation of the size and area of the metal plate according to customer need, the metal plate 801 may be applied during or after encapsulation of the power module 800. During encapsulation a cavity may be formed on the upper side of the encapsulation and the metal plate may be formed by forming a seed layer and subsequently via galvanic deposition. Alternatively, the metal plate 801 may be attached to a mold foil inserted into the mold tool prior to injecting the mold compound into the mold tool. After molding, the copper plate peels off from the mold foils and remains a part of the mold body.

In the following, the power semiconductor package, the system and the method for fabricating a power semiconductor package are further explained using specific examples.

Example 1 is a power semiconductor package, comprising: a power electronic substrate comprising at least a first electrically conductive layer arranged on an electrically insulating layer, a plurality of power semiconductor dies arranged on and electrically coupled to the first electrically conductive layer such that a first side of the power semiconductor dies faces the first electrically conductive layer, wherein the power semiconductor dies form a half bridge circuit comprising at least one low side die and at least one high side die, a first contact clip connecting a first type power electrode of the low side die to a second type power electrode of the high side die, wherein the second type power electrode of the high side die is arranged on a second side of the high side die, opposite the first side, and wherein the first contact clip is arranged above the second side of the high side die, a second contact clip electrically connected to a first type power electrode on the first side of the high side die, wherein an upper portion of the second contact clip is arranged vertically above the first contact clip, and a molded body encapsulating the power semiconductor dies.

Example 2 is the power semiconductor package of example 1, wherein a first lower portion of the second contact clip is joined to a first pad of the first electrically conductive layer and wherein the first lower portion and/or the first pad is at least partially exposed from the molded body and forms a first type DC power terminal of the power semiconductor package.

Example 3 is the power semiconductor package of example 1, wherein the upper portion of the second contact clip is at least partially exposed from the molded body and forms a first type DC power terminal of the power semiconductor package.

Example 4 is the power semiconductor package of example 3, further comprising: a second type DC power terminal of the power semiconductor package provided by a second pad of the first electrically conductive layer, and wherein the first type DC power terminal is arranged in a first plane and the second type DC power terminal is arranged in a parallel second plane.

Example 5 is the power semiconductor package of one of the preceding examples, wherein an upper portion of the first contact clip and the upper portion of the second contact clip are arranged in parallel planes.

Example 6 is the power semiconductor package of one of the preceding examples, wherein the high side die is arranged on a third pad of the first electrically conductive layer, and wherein a second lower portion of the second contact clip is joined to the third pad.

Example 7 is the power semiconductor package of example 6, wherein the low side die is arranged on a fourth pad of the first electrically conductive layer, wherein the third and fourth pads are arranged laterally next to each other, and wherein first edges of the third and fourth pads are part of an outer edge region of the power electronic substrate, the first edges being parallel to each other.

Example 8 is the power semiconductor package of one of the preceding examples, further comprising: a third contact clip connecting a second pad of the first electrically conductive layer to a second type electrode of the low side die, wherein a lower portion of the third contact clip and/or the second pad is exposed from the molded body and forms a second type DC power terminal of the power semiconductor package.

Example 9 is the power semiconductor package of example 8, wherein the upper portion of the second contact clip is arranged vertically above the third contact clip.

Example 10 is the power semiconductor package of one of the preceding examples, further comprising: press fit pins joined to further pads of the first electrically conductive layer, the press fit pins being exposed from the molded body and the press fit pins forming gate terminals and/or sensing terminals of the power semiconductor package.

Example 11 is the power semiconductor package of one of the preceding examples, wherein the first electrically conductive layer is arranged on a first side of the electrically insulating layer and wherein a second electrically conductive layer is arranged on an opposite second side of the electrically insulating layer, wherein the second electrically conductive layer is exposed from the molded body, and wherein the second electrically conductive layer is configured to be coupled to a heatsink.

Example 12 is the power semiconductor package of one of the preceding examples, wherein a first type DC power terminal, a second type DC power terminal and a phase current terminal of the power semiconductor package are arranged in a plane above the first contact clip.

Example 13 is the power semiconductor package of example 12, further comprising: ribbons or clips or lower portions of the second type DC power terminal and the phase current terminal connecting the second type DC power terminal and the phase current terminal to the substrate.

Example 14 is the power semiconductor package of example 13, wherein the ribbon or clip or lower portion of the second type DC power terminal and the ribbon or clip or lower portion of the phase current terminal have the same orientation.

Example 15 is the power semiconductor package of one of examples 12 to 14, further comprising: an additional metal bar, the additional metal bar being arranged coplanar with the first and second type DC power terminals and the phase current terminal, and the additional metal bar being arranged vertically above the first contact clip in a gap between the second contact clip and the phase current terminal.

Example 16 is a system comprising: the power semiconductor package of one of the preceding claims, and a first type DC busbar and a second type DC busbar configured to electrically connect the power semiconductor package to a DC link capacitor, wherein the first type DC busbar and the second type DC busbar are at least partially arranged in two parallel planes.

Example 17 is the system of example 16, wherein the second type DC busbar comprises a dummy portion, wherein a direct current path between the DC link capacitor and the power semiconductor package does not go through the dummy portion, and wherein the dummy portion is configured to extend a length of a portion of the second type DC busbar that is parallel to the first type DC busbar.

Example 18 is a method for fabricating a power semiconductor package, the method comprising: providing a power electronic substrate comprising at least a first electrically conductive layer arranged on an electrically insulating layer, arranging a plurality of power semiconductor dies on the first electrically conductive layer such that a first side of the power semiconductor dies faces the first electrically conductive layer and electrically coupling the power semiconductor dies to the first electrically conductive layer, wherein the power semiconductor dies form a half bridge circuit comprising at least one low side die and at least one high side die, connecting a first type electrode of the low side die to a second type electrode of the high side die using a first contact clip, wherein the second type electrode of the high side die is arranged on a second side of the high side die, opposite the first side, and wherein the first contact clip is arranged above the second side of the high side die, connecting a second contact clip to a first type electrode on the first side of the high side die, wherein an upper portion of the second contact clip is arranged vertically above the first contact clip, and encapsulating the power semiconductor dies with a molded body.

Example 19 is the method of example 18, further comprising: joining a first lower portion of the second contact clip to a first pad of the first electrically conductive layer, and at least partially exposing the first lower portion and/or the first pad from the molded body, thereby forming a first type DC power terminal of the power semiconductor package.

Example 20 is the method of example 18, further comprising: at least partially exposing the upper portion of the second contact clip from the molded body and thereby forming a first type DC power terminal of the power semiconductor package.

Example 21 is an apparatus comprising means for performing the method according to anyone of examples 18 to 20.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A power semiconductor package, comprising:
a power electronic substrate comprising at least a first electrically conductive layer arranged on an electrically insulating layer;
a plurality of power semiconductor dies arranged on and electrically coupled to the first electrically conductive layer, such that a first side of the power semiconductor dies faces the first electrically conductive layer, wherein the power semiconductor dies form a half bridge circuit comprising at least one low side die and at least one high side die;
a first contact clip connecting a first type power electrode of the at least one low side die to a second type power electrode of the at least one high side die, wherein the second type power electrode is arranged on a second side of the at least one high side die, opposite the first side, and wherein the first contact clip is arranged above the second side of the at least one high side die;
a second contact clip electrically connected to a first type power electrode on the first side of the at least one high side die, wherein an upper portion of the second contact clip is arranged vertically above the first contact clip; and
a molded body encapsulating the power semiconductor dies.

2. The power semiconductor package of claim 1, wherein a first lower portion of the second contact clip is joined to a first pad of the first electrically conductive layer, and wherein the first lower portion and/or the first pad is at least partially exposed from the molded body and forms a first type DC power terminal of the power semiconductor package.

3. The power semiconductor package of claim 1, wherein the upper portion of the second contact clip is at least partially exposed from the molded body and forms a first type DC power terminal of the power semiconductor package.

4. The power semiconductor package of claim 3, further comprising:
a second type DC power terminal provided by a second pad of the first electrically conductive layer,
wherein the first type DC power terminal is arranged in a first plane and the second type DC power terminal is arranged in a parallel second plane.

5. The power semiconductor package of claim 1, wherein an upper portion of the first contact clip and the upper portion of the second contact clip are arranged in parallel planes.

6. The power semiconductor package of claim 1, wherein the at least one high side die is arranged on a third pad of the first electrically conductive layer, and wherein a second lower portion of the second contact clip is joined to the third pad.

7. The power semiconductor package of claim 6, wherein the at least one low side die is arranged on a fourth pad of the first electrically conductive layer, wherein the third and fourth pads are arranged laterally next to each other, and wherein first edges of the third and fourth pads are part of an outer edge region of the power electronic substrate, the first edges being parallel to each other.

8. The power semiconductor package of claim 1, further comprising:
a third contact clip connecting a second pad of the first electrically conductive layer to a second type electrode of the at least one low side die,
wherein a lower portion of the third contact clip and/or the second pad is exposed from the molded body and forms a second type DC power terminal of the power semiconductor package.

9. The power semiconductor package of claim 8, wherein the upper portion of the second contact clip is arranged vertically above the third contact clip.

10. The power semiconductor package of claim 1, further comprising:
a plurality of press fit pins joined to further pads of the first electrically conductive layer, the press fit pins being exposed from the molded body and forming gate terminals and/or sensing terminals of the power semiconductor package.

11. The power semiconductor package of claim 1, wherein the first electrically conductive layer is arranged on a first side of the electrically insulating layer, wherein a second electrically conductive layer is arranged on an opposite second side of the electrically insulating layer, wherein the second electrically conductive layer is exposed from the molded body, and wherein the second electrically conductive layer is configured to be coupled to a heatsink.

12. The power semiconductor package of claim 1, further comprising:
a first type DC power terminal, a second type DC power terminal and a phase current terminal are arranged in a plane above the first contact clip.

13. The power semiconductor package of claim 12, further comprising:
a plurality of ribbons, clips or lower portions of the second type DC power terminal and the phase current terminal connecting the second type DC power terminal and the phase current terminal to the substrate.

14. The power semiconductor package of claim 13, wherein the ribbon, clip or lower portion of the second type DC power terminal and the ribbon, clip or lower portion of the phase current terminal have the same orientation.

15. The power semiconductor package of claim 12, further comprising:
an additional metal bar arranged coplanar with the first and second type DC power terminals and the phase current terminal,
wherein the additional metal bar is arranged vertically above the first contact clip in a gap between the second contact clip and the phase current terminal.

16. The power semiconductor package of claim 1, further comprising:
a metal plate exposed from the molded body.

17. A system, comprising:
the power semiconductor package of claim 1; and
a first type DC busbar and a second type DC busbar configured to electrically connect the power semiconductor package to a DC link capacitor,
wherein the first type DC busbar and the second type DC busbar are at least partially arranged in two parallel planes.

18. The system of claim 17, wherein the second type DC busbar comprises a dummy portion, wherein a direct current path between the DC link capacitor and the power semiconductor package does not go through the dummy portion, and wherein the dummy portion is configured to extend a length of a portion of the second type DC busbar that is parallel to the first type DC busbar.

19. A method for fabricating a power semiconductor package, the method comprising:
providing a power electronic substrate comprising at least a first electrically conductive layer arranged on an electrically insulating layer;
arranging a plurality of power semiconductor dies on the first electrically conductive layer, such that a first side of the power semiconductor dies faces the first electrically conductive layer and electrically coupling the power semiconductor dies to the first electrically conductive layer, wherein the power semiconductor dies form a half bridge circuit comprising at least one low side die and at least one high side die;
connecting a first type electrode of the at least one low side die to a second type electrode of the at least one high side die using a first contact clip, wherein the second type electrode is arranged on a second side of the at least one high side die, opposite the first side, and wherein the first contact clip is arranged above the second side of the at least one high side die;
connecting a second contact clip to a first type electrode on the first side of the at least one high side die, wherein an upper portion of the second contact clip is arranged vertically above the first contact clip; and
encapsulating the power semiconductor dies with a molded body.

20. The method of claim 19, further comprising:
joining a first lower portion of the second contact clip to a first pad of the first electrically conductive layer; and
at least partially exposing the first lower portion and/or the first pad from the molded body, thereby forming a first type DC power terminal of the power semiconductor package.

21. The method of claim 19, further comprising:
at least partially exposing the upper portion of the second contact clip from the molded body, thereby forming a first type DC power terminal of the power semiconductor package.
